(19) United States
(12) Patent Application Publication
(10) Pub. No.: US 2007/0134850 A1
(43) Pub. Date: Jun. 14, 2007

(54) Method of manufacturing wiring board

(75) Inventor: Takahiro Imai, Sakata (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/607,111

(22) Filed: Nov. 30, 2006

(30) Foreign Application Priority Data
Dec. 12, 2005 (JP) 2005-357892

(51) Int. Cl. H01L 21/00

(52) U.S. Cl. 438/123

(57) ABSTRACT

A method of manufacturing a wiring board including: providing a substrate including a base substrate, a conductive film formed on a surface of the base substrate, and a plurality of leads formed on the conductive film; forming a resist layer which partially covers the conductive film in a region between two adjacent leads of the plurality of leads so that the resist layer contacts the two leads; patterning the conductive film to form a conductive pattern which electrically connects the leads; electroplating the leads by causing an electric current to flow through the leads via the conductive pattern; and cutting the conductive pattern to electrically insulate the leads.

Japanese Patent Application No. 2005-357892, filed on Dec. 12, 2005, is hereby incorporated by reference in its entirety.

### BACKGROUND OF THE INVENTION

The present invention relates to a method of manufacturing a wiring board.

A wiring board has been known which has an interconnect with a plating layer formed on its surface (see JP-A-5-21536, for example). It has been known to form the plating layer by electroplating. In this case, a plating lead may be utilized to efficiently plate a plurality of interconnects. The size of a base substrate can be reduced by making it unnecessary to provide the space for forming the plating lead on the base substrate. In order to improve the reliability of the interconnect, it is preferable that the plating layer be formed to cover a large area of the surface of the interconnect.

### SUMMARY

According to one aspect of the invention, there is provided a method of manufacturing a wiring board comprising:
providing a substrate including a base substrate, a conductive film formed on a surface of the base substrate, and a plurality of leads formed on the conductive film;
forming a resist layer which partially covers the conductive film in a region between two adjacent leads of the plurality of leads so that the resist layer contacts the two leads;
patterning the conductive film by removing exposed portions of the conductive film which are not covered by the leads and the resist layer to form a conductive pattern which electrically connects the leads;
electroplating the leads by causing an electric current to flow through the leads via the conductive pattern; and
cutting the conductive pattern to electrically insulate the leads.

### BRIEF DESCRIPTION OF THE SEVERAL VIEWS OF THE DRAWING

FIGS. 1A and 1B are views illustrative of a method of manufacturing a wiring board.

FIGS. 2A to 2C are views illustrative of a method of manufacturing a wiring board.

FIGS. 3A and 3B are views illustrative of a method of manufacturing a wiring board.

FIGS. 4A to 4C are views illustrative of a method of manufacturing a wiring board.

FIGS. 5A to 5C are views illustrative of a method of manufacturing a wiring board.

FIGS. 6A and 6B are views illustrative of a method of manufacturing a wiring board.

FIGS. 7A and 7B are views illustrative of a method of manufacturing a wiring board.

FIG. 8 is a view illustrative of a method of manufacturing a wiring board.

FIG. 9 is a view illustrative of a modification of a method of manufacturing a wiring board.

FIGS. 10A and 10B are views illustrative of another modification of a method of manufacturing a wiring board.

FIGS. 11A and 11B are views illustrative of the other modification of a method of manufacturing a wiring board.

### DETAILED DESCRIPTION OF THE EMBODIMENT

The invention may provide a method of inexpensively and efficiently manufacturing a highly reliable wiring board.

(1) According to one embodiment of the invention, there is provided a method of manufacturing a wiring board comprising:
providing a substrate including a base substrate, a conductive film formed on a surface of the base substrate, and a plurality of leads formed on the conductive film;
forming a resist layer which partially covers the conductive film in a region between two adjacent leads of the plurality of leads so that the resist layer contacts the two leads;
patterning the conductive film by removing exposed portions of the conductive film which are not covered by the leads and the resist layer to form a conductive pattern which electrically connects the leads;
electroplating the leads by causing an electric current to flow through the leads via the conductive pattern; and
cutting the conductive pattern to electrically insulate the leads.

According to this embodiment, the leads are electroplated by utilizing the conductive pattern. Therefore, this embodiment makes it unnecessary to provide a region for forming a plating lead on the base substrate, whereby a wiring board can be manufactured using a small base substrate. This enables a wiring board to be efficiently manufactured due to easy handling of the base substrate. Moreover, the cost of the base substrate can be reduced. According to this embodiment, the plating layer can be formed to cover the side surface of the lead. Therefore, this embodiment enables a highly reliable wiring board to be manufactured.

(2) This method of manufacturing a wiring board may further comprise forming a second resist layer which partially covers the leads between the step of forming the conductive pattern and the step of electroplating.

(3) In this method of manufacturing a wiring board, the second resist layer may be formed so that the resist layer is exposed.

(4) In this method of manufacturing a wiring board, the second resist layer may be formed to cover the resist layer.

(5) In this method of manufacturing a wiring board, the resist layer may be formed to have a thickness smaller than the thickness of the leads.

Embodiments of the invention will be described below with reference to the drawings. Note that the invention is not limited to the following embodiments. The invention includes configuration in which the components in the following description are arbitrarily combined.

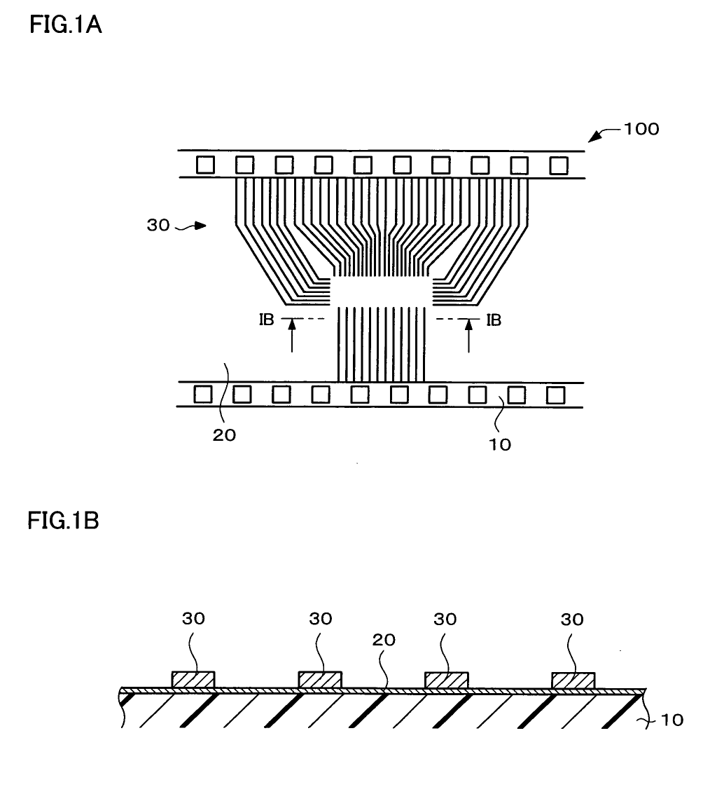

FIGS. 1A to 8 are views illustrative of a method of manufacturing a wiring board according to an embodiment to which the invention is applied.

The method of manufacturing a wiring board according to this embodiment includes providing a substrate 100 shown in FIGS. 1A and 1B. FIG. 1A is a top view of the substrate 100. FIG. 1B is a partially enlarged view along the line 1B-1B in FIG. 1A. The configuration of the substrate 100 is described below.

As shown in FIGS. 1A and 1B, the substrate 100 includes a base substrate 10. The material and the structure of the base substrate 10 are not particularly limited. A known substrate may be used. The material for the base substrate 10 may be an organic or inorganic material, or may be a composite of these materials. As the base substrate 10, a substrate or a film formed of polyethyleneterephthalate (PET) may be used, for example. A flexible substrate formed of a polyimide resin may be used as the base substrate 10. As examples of the base substrate 10 formed of an inorganic material, a ceramic substrate and a glass substrate can be given.

As shown in FIGS. 1A and 1B, the substrate 100 includes a conductive film 20 formed on the surface of the base substrate 10. The conductive film 20 may be formed of a single metal layer or a plurality of metal layers. The material for the conductive film 20 is not particularly limited. For example, Ti or Ti—W may be used as the material for the conductive film 20.

As shown in FIGS. 1A and 1B, the substrate 100 includes a plurality of leads 30 formed on the conductive film 20. The leads 30 are formed on the surface of the conductive film 20. The formation region of the leads 30 is not particularly limited. The lead 30 may be formed to reach the edge of the conductive film 20. The configuration of the lead 30 is not particularly limited. The lead 30 may be formed of a single metal layer or a plurality of metal layers. The material for the lead 30 is not particularly limited. The lead 30 may be formed of a metal such as copper (Cu), chromium (Cr), or nickel (Ni).

The substrate 100 may further include other interconnects formed in the base substrate 10 (not shown).

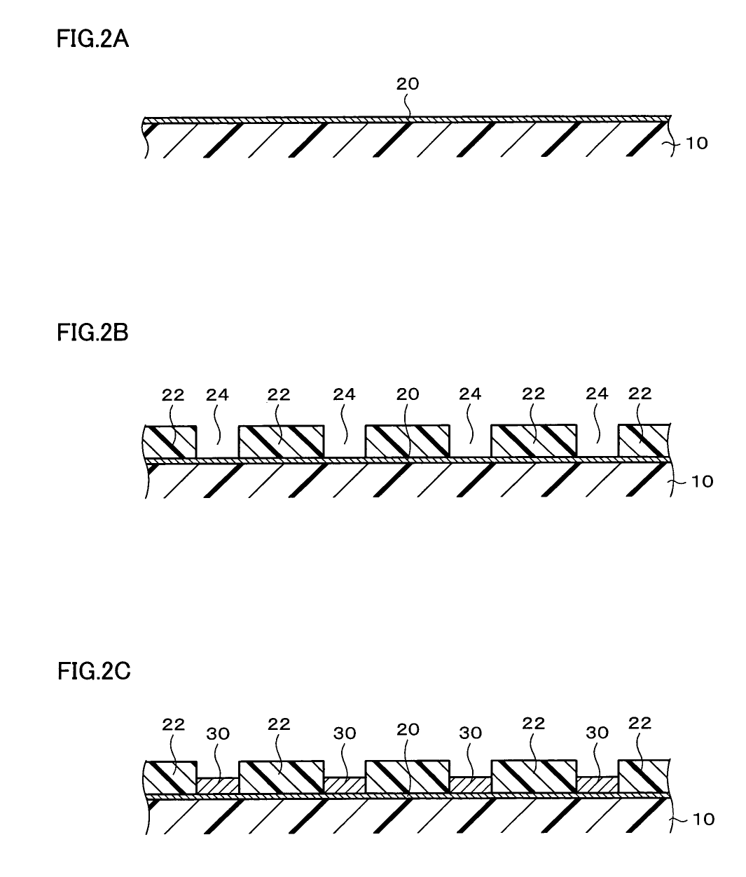

The method of forming the substrate 100 is not particularly limited. An example of the method of forming the substrate 100 is described below with reference to FIGS. 2A to 2C.

As shown in FIG. 2A, the conductive film 20 is formed on the base substrate 10. The conductive film 20 may be formed of a single layer or a plurality of layers. The conductive film 20 may be formed by sputtering. The conductive film 20 may be formed of Ti or Ti—W. The conductive film 20 may be formed by bonding conductive foil to the base substrate 10. In this case, the conductive foil may be directly bonded to the base substrate 10, or may be bonded to the base substrate 10 through an adhesive (not shown).

As shown in FIG. 2B, a resist layer 22 is formed on the conductive film 20. The resist layer 22 is formed to partially cover the conductive film 20. The resist layer 22 may have an opening 24 which exposes the region for forming the lead 30. Specifically, the resist layer 22 is formed to expose (only) the region for forming the lead 30.

As shown in FIG. 2C, the lead 30 is formed in the exposed region (region which coincides with the opening 24) of the conductive film 20 which is not covered with the resist layer 22. The lead 30 may be formed by providing a conductive material in the opening 24, for example. The lead 30 may be formed by plating (including electroplating and electroless plating), for example. The lead 30 may be formed of Cu, for example. The lead 30 may be formed of a single conductive material, or may be formed by stacking a plurality of conductive materials.

The substrate 100 (lead 30) shown in FIGS. 1A and 1B may be formed by removing the resist layer 22. According to this method, the shape of the lead 30 is restricted by the shape of the opening 24 in the resist layer 22. Therefore, this method allows the lead 30 to be formed into a shape conforming to the design.

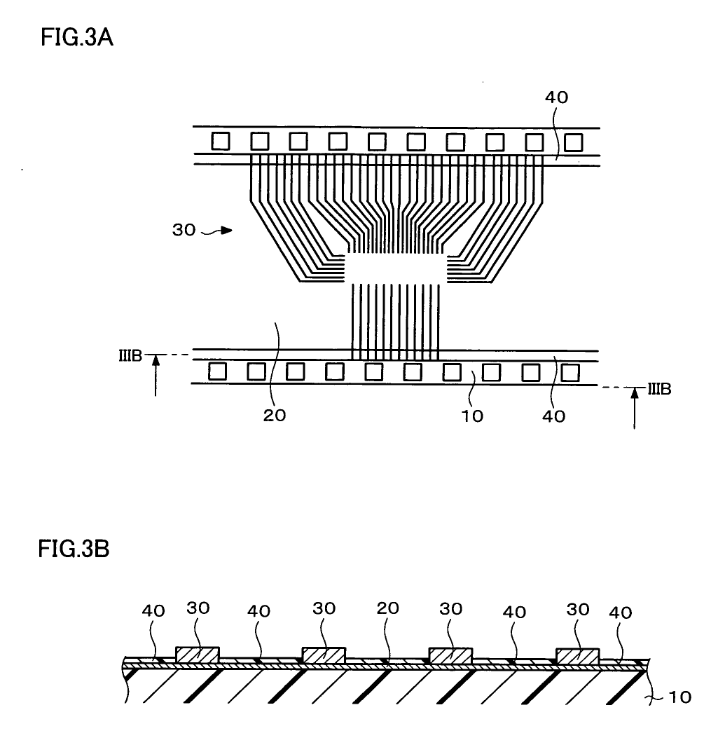

The method of manufacturing a wiring board according to this embodiment includes forming a resist layer 40, as shown in FIGS. 3A and 3B. The resist layer 40 is formed to partially cover the conductive film 20 in the region between two adjacent leads 30. The resist layer 40 is formed to contact two adjacent leads 30. In other words, the resist layer 40 which partially covers the conductive film 20 in the region between the leads 30 is formed so that the resist layer 40 contacts two adjacent leads 30.

In this embodiment, the resist layer 40 is formed to expose the top surface of the lead 30, as shown in FIG. 3B. In this embodiment, the resist layer 40 is formed to have a thickness smaller than that of the lead 30. Specifically, the resist layer 40 is formed so that the top surface of the lead 30 is exposed and the side surface of the lead 30 is partially exposed. The resist layer 40 may be formed to have a thickness equal to or smaller than half of the thickness of the lead 30. The resist layer 40 may be formed to have the same thickness as the conductive film 20.

The method of forming the resist layer 40 is not particularly limited. The resist layer 40 may be formed by applying a resin material and curing the applied resin material, for example. In this case, the thickness of the resist layer 40 may be controlled by adjusting the amount and the viscosity of the resin material. The method of providing the resin material is not particularly limited. The resin material may be provided using an inkjet method, for example.

The formation region of the resist layer 40 is not particularly limited. The resist layer 40 may be formed in the edge region of the conductive film 20, as shown in FIG. 3A. The size of the resist layer 40 is not particularly limited. For example, the resist layer 40 may be formed so that the width of the resist layer 40 (dimension in the direction along the lead 30) is (almost) the same as the width of the lead 30. The resist layer 40 may be formed to have an (almost) square shape between two adjacent leads 30. The resist layer 40 may be formed only between adjacent leads 30. As shown in FIG. 3A, the resist layer 40 may also be formed in the region outside the lead 30. In this case, the resist layer 40 is formed on both sides of each lead 30.

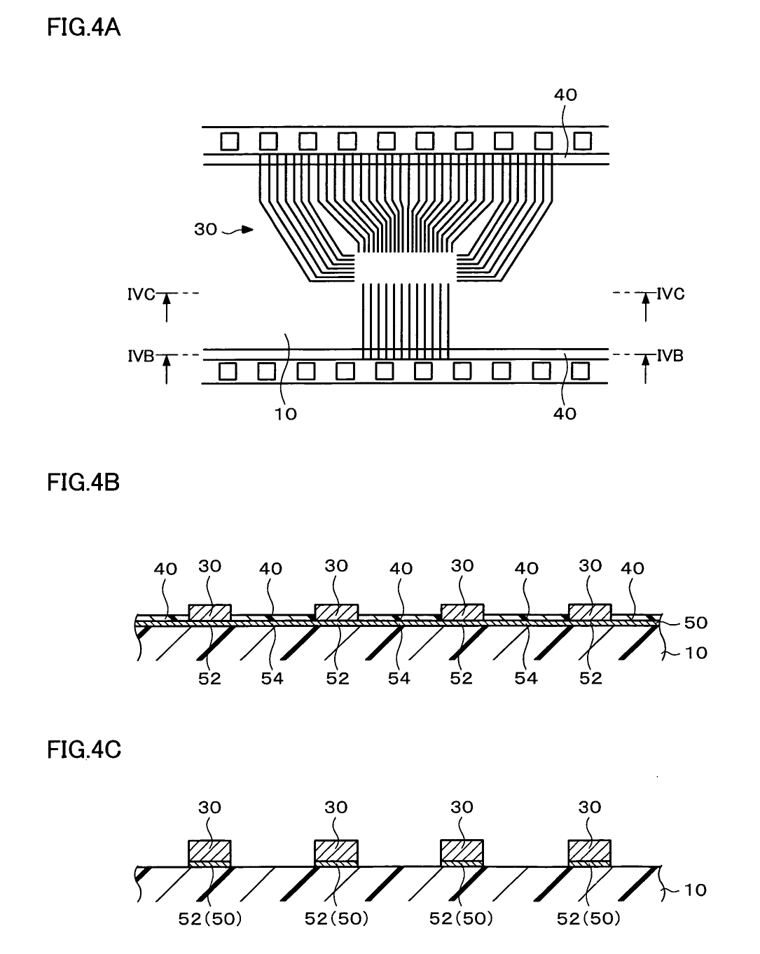

The method of manufacturing a wiring board according to this embodiment includes patterning the conductive film 20 to form a conductive pattern 50 which electrically connects the leads 30, as shown in FIGS. 4A to 4C. In this step, the conductive film 20 is patterned (conductive pattern 50 is formed) by removing the exposed regions of the conductive film 20 in which the conductive film 20 is not covered with the leads 30 and the resist layer 40. This allows the conductive pattern 50 to have an underlying portion 52 positioned under the lead 30 and an exposed portion 54 which is not covered with the lead 30, as shown in FIGS. 4B and 4C. According to the conductive pattern 50, the exposed portion 54 contacts two adjacent underlying portions 52 to electrically connect two adjacent leads 30, as shown in FIG. 4B. Specifically, the conductive pattern 50 is formed to electrically connect the leads 30. The exposed portion 54 may be referred to as a region positioned under the resist layer 40.

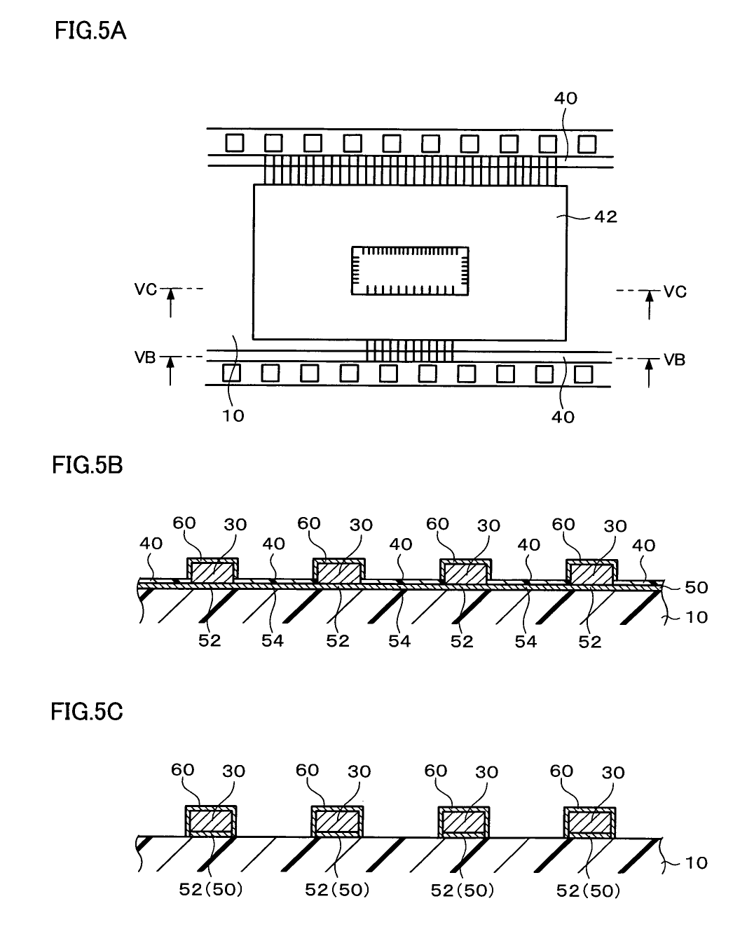

The method of manufacturing a wiring board according to this embodiment includes forming a second resist layer 42 which partially covers the leads 30 (see FIG. 5A). The second resist layer 42 is formed to expose the portion of the lead 30 used for electrical connection with another electronic part. The exposed portion of the lead 30 which is not covered with the second resist layer 42 may be referred to as an electrical connection section. Note that this step is performed after the step of forming the conductive pattern 50.

In the method of manufacturing a wiring board according to this embodiment, the second resist layer 42 is formed to avoid the resist layer 40 (so that the resist layer 40 is exposed) (see FIG. 5A). In this case, the second resist layer 42 may be formed at an interval from the resist layer 40, as shown in FIG. 5A. The second resist layer 42 may also be formed to be adjacent to the resist layer 40 (not shown). As a modification, the second resist layer 42 may be formed to (completely) cover the resist layer 40. In this case, the lead 30 and the conductive pattern 50 may be provided with electric power for electroplating by utilizing the exposed portion (electrical connection section) of the lead 30 which is not covered with the second resist layer 42. As another modification, electroplating described later may be carried out without utilizing the second resist layer 42.

The method of manufacturing a wiring board according to this embodiment includes electroplating the leads 30 by causing an electric current to flow through the leads 30 via the conductive pattern 50. A plating layer 60 is formed by this step, as shown in FIGS. 5A to 5C. The plating layer 60 is formed to cover the top surface and the side surface of the lead 30 in the area in which the lead 30 is not covered with the resist layer 40 and the second resist layer 42, as shown in FIGS. 5B and 5C. In this step, the plating layer 60 is formed to cover the side surface of the conductive pattern 50 (underlying section 52) in the area in which the conductive pattern 50 is not covered with the resist layer 40 and the second resist layer 42, as shown in FIG. 5C. The plating layer 60 may be formed of Au, for example.

In the method of manufacturing a wiring board according to this embodiment, the plating layer 60 is formed by electroplating. In this step, an electric current is caused to flow through the leads 30 via the conductive pattern 50. The conductive pattern 50 is electrically connected with the leads 30, as described above. Therefore, an electric current can be collectively caused to flow through the leads 30 by utilizing the conductive pattern 50, whereby a wiring board can be efficiently manufactured. In this step, part of the conductive pattern 50 may be exposed by removing the resist layer 40, and electric power may be supplied to the conductive pattern 50 by utilizing the exposed region.

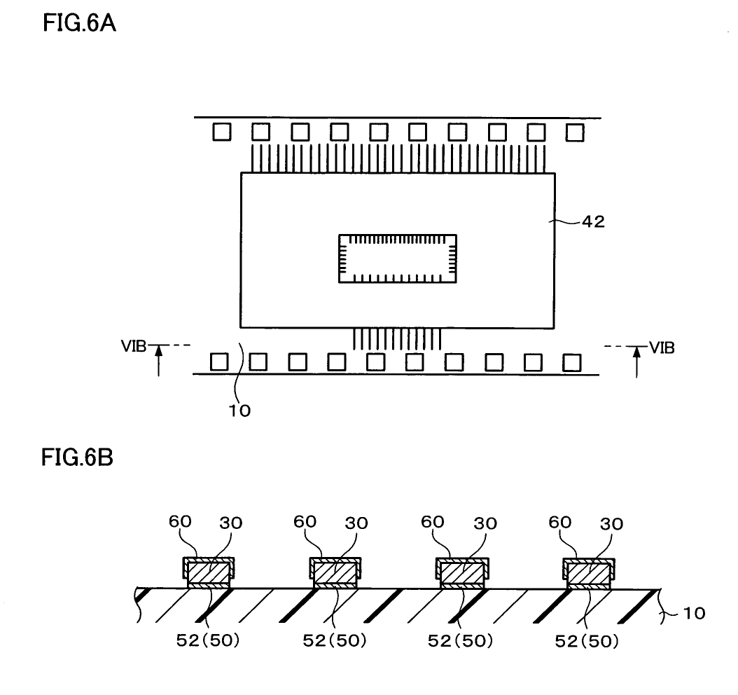

The method of manufacturing a wiring board according to this embodiment includes cutting the conductive pattern 50 to electrically insulate (separate) the leads 30. For example, the exposed portions 54 of the conductive pattern 50 which are not covered with the leads 30 may be completely removed by this step, as shown in FIGS. 6A and 6B.

This step may include removing the resist layer 40. For example, the resist layer 40 may be removed to expose the exposed portions 54, and the exposed portions 54 may be cut (removed) thereafter.

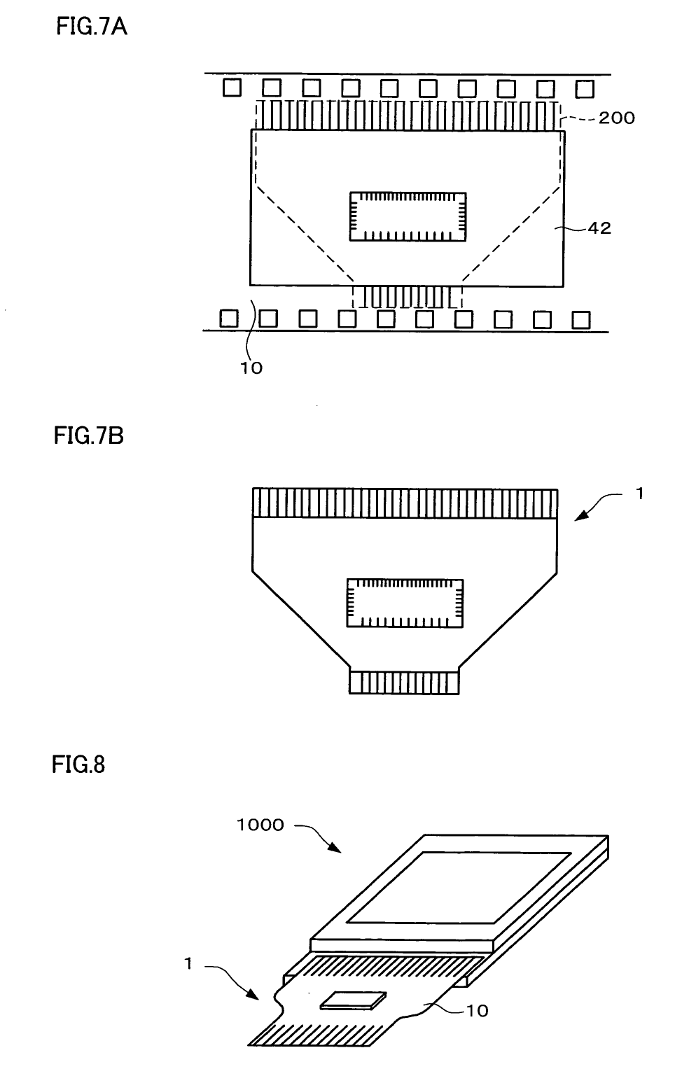

The method of manufacturing a wiring board according to this embodiment may further include cutting the base substrate 10. Specifically, the base substrate 10 may be cut along a broken line 200 shown in FIG. 7A to manufacture a wiring board 1 shown in FIG. 7B.

According to this embodiment, the leads 30 are electroplated by utilizing the conductive pattern 50, as described above. Specifically, this embodiment makes it unnecessary to provide a plating lead for causing an electric current to flow through the leads 30. Therefore, this embodiment allows a wiring board to be manufactured utilizing a small base substrate, whereby a wiring board can be efficiently manufactured. Moreover, since the base substrate can be efficiently utilized, the manufacturing cost of the wiring board can be reduced. According to this embodiment, the plating layer which covers the side surface of the lead 30 can be efficiently formed. Therefore, this embodiment enables efficient manufacture of a highly reliable wiring board.

FIG. 8 shows a display device 1000 as an example of an electronic instrument including a wiring board manufactured using the method according to the embodiment to which the invention is applied. The display device 1000 may be a liquid crystal display device, an electroluminescent (EL) display device, or the like.

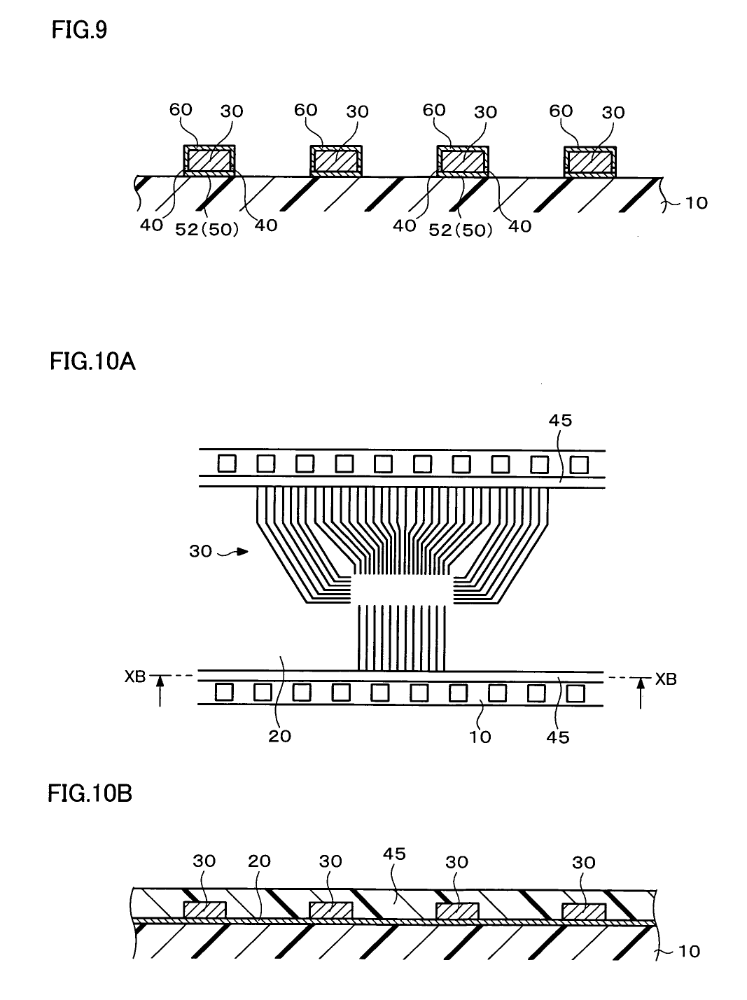

FIG. 9 is a view illustrative of a modification of this embodiment.

In this embodiment, the leads 30 are electrically insulated so that the resist layer 40 and the exposed portion 54 partially remain, as shown in FIG. 9. For example, the resist layer 40 and the exposed portion 54 (conductive pattern 50) may be removed only in the area in which the resist layer 40 and the exposed portion 54 are not covered with the plating layer 60, as shown in FIG. 9. This enables manufacture of a highly reliable wiring board in which the lead 30 is not exposed.

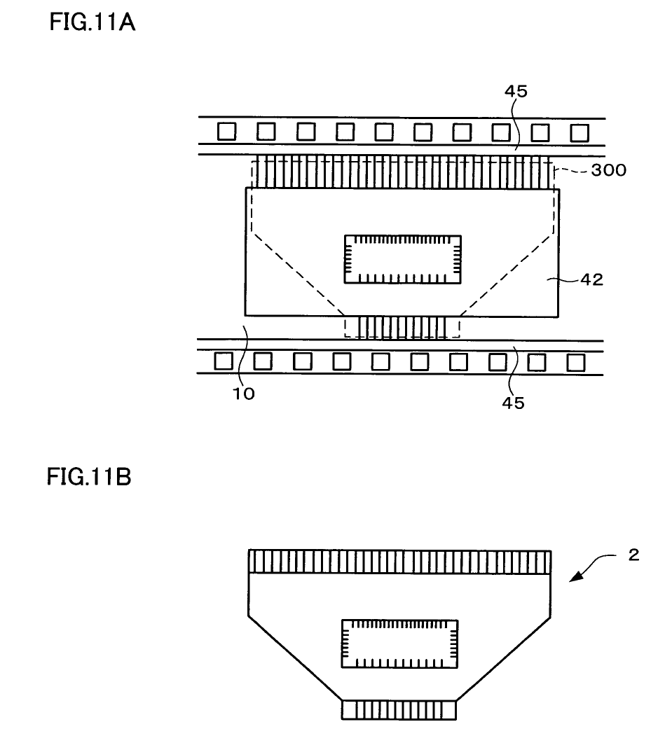

FIGS. 10A to 11B are views illustrative of another modification of this embodiment.

The method of manufacturing a wiring board according to this embodiment includes forming a resist layer 45 on the substrate 100. As shown in FIGS. 10A and 10B, the resist layer 45 is formed to cover the leads 30. The resist layer 45 may be formed to cover the end of the lead 30.

The method of manufacturing a wiring board according to this embodiment includes forming the second resist layer 42 on the substrate 100. The second resist layer 42 may be formed to expose the resist layer 45, or may be formed to cover the resist layer 45 (not shown).

The method of manufacturing a wiring board according to this embodiment includes cutting the base substrate 10, as shown in FIGS. 11A and 11B. Specifically, the base substrate 10 is cut along a broken line 300 shown in FIG. 11A to manufacture a wiring board 2 shown in FIG. 11B.

In this embodiment, the conductive pattern 50 is cut in the step of cutting the base substrate 10 to electrically insulate (separate) the leads 30. In more detail, the method of manufacturing a wiring board according to this embodiment includes cutting the base substrate 10 along the broken line 300 shown in FIG. 11A. As shown in FIG. 11A, the region enclosed by the broken line 300 is a region which does not include the resist layer 45. Therefore, the leads 30 can be electrically insulated by cutting the base substrate 10 along the broken line 300. Specifically, this embodiment makes it unnecessary to incorporate a step of electrically insulating the leads 30, whereby a wiring board can be more efficiently manufactured. This step may be referred to as a step of completely removing the exposed portions 54 of the conductive pattern 50 which are not covered with the leads 30.

According to this method, a plating layer can be formed to cover the top surface and the side surface of the lead 30 and the side surface of the conductive pattern 50 (underlying section 52). Therefore, this method enables efficient manufacture of a highly reliable wiring board.

The invention is not limited to the above-described embodiments, and various modifications can be made. For example, the invention includes various other configurations substantially the same as the configurations described in the embodiments (in function, method and result, or in objective and result, for example). The invention also includes a configuration in which an unsubstantial portion in the described embodiments is replaced. The invention also includes a configuration having the same effects as the configurations described in the embodiments, or a configuration able to achieve the same objective. Further, the invention includes a configuration in which a publicly known technique is added to the configurations in the embodiments.

Although only some embodiments of the invention have been described in detail above, those skilled in the art will readily appreciate that many modifications are possible in the embodiments without materially departing from the novel teachings and advantages of this invention. Accordingly, all such modifications are intended to be included within the scope of the invention.

What is claimed is:

1. A method of manufacturing a wiring board comprising:
providing a substrate including a base substrate, a conductive film formed on a surface of the base substrate, and a plurality of leads formed on the conductive film;
forming a resist layer which partially covers the conductive film in a region between two adjacent leads of the plurality of leads so that the resist layer contacts the two leads;
patterning the conductive film by removing exposed portions of the conductive film which are not covered by the leads and the resist layer to form a conductive pattern which electrically connects the leads;
electroplating the leads by causing an electric current to flow through the leads via the conductive pattern; and
cutting the conductive pattern to electrically insulate the leads.

2. The method of manufacturing a wiring board as defined in claim 1, further comprising:
forming a second resist layer which partially covers the leads between the step of forming the conductive pattern and the step of electroplating.

3. The method of manufacturing a wiring board as defined in claim 2,
wherein the second resist layer is formed so that the resist layer is exposed.

4. The method of manufacturing a wiring board as defined in claim 2,
wherein the second resist layer is formed to cover the resist layer.

5. The method of manufacturing a wiring board as defined in claim 1,
wherein the resist layer is formed to have a thickness smaller than the thickness of the leads.
